(19) United States
(12) Patent Application Publication
(10) Pub. No.: US 2019/0095000 A1
(43) Pub. Date: Mar. 28, 2019

(54) MUTUAL CAPACITANCE TOUCH DISPLAY PANEL WITH FINGERPRINT RECOGNITION AND LIQUID CRYSTAL DISPLAY APPARATUS

(71) Applicant: Wuhan China Star Optoelectronics Technology Co., Ltd, Wuhan, Hubei (CN)

(72) Inventors: Yao-li HUANG, Shenzhen, Guangdong (CN); Xinglong HE, Shenzhen, Guangdong (CN)

(21) Appl. No.: 15/736,696

(22) PCT Filed: Nov. 6, 2017
(86) PCT No.: PCT/CN2017/109586

§ 371 Date: Dec. 14, 2017

(30) Foreign Application Priority Data
Sep. 26, 2017 (CN) 201710883133.1

(51) Int. Cl. G06F 3/044; G06K 9/00; H01L 27/12; G06F 1/16

(52) U.S. Cl. CPC G06F 3/044; G06K 9/00087; G09G 2310/0264; G06F 1/1652; G06F 2203/04112; H01L 27/1214

(57) ABSTRACT

The present application provides a mutual capacitance touch display panel with fingerprint recognition, including a capacitance module and a display module, the capacitance module includes: a plurality of first electrodes parallel to each other used for fingerprint recognition driving lines; a plurality of second electrodes parallel to each other, arranged to intersect with the plurality of first electrodes to form a plurality of parasitic capacitances, the second electrodes are used for collection lines for fingerprint recognition; a first fingerprint recognition chip electrically connected to the first electrodes, respectively, the first fingerprint recognition chip outputting driving signals to the first electrodes in a time division manner; a second fingerprint recognition chip electrically connected to the second electrodes, the second fingerprint recognition chip receiving sensing signals of the second electrodes to obtain the parasitic capacitances at intersections of the second electrodes and the first electrodes and obtaining fingerprint data of the user.

### RELATED APPLICATIONS

The present application is a National Phase of International Application Number PCT/CN2017/109586, filed Nov. 6, 2017, and claims the priority of China Application No. 201710883133.1, filed Sep. 26, 2017.

### FIELD OF THE DISCLOSURE

The disclosure relates to a display technical field, and more particularly to a mutual capacitance touch display panel with fingerprint recognition and a liquid crystal display apparatus.

### BACKGROUND

Fingerprints are the lines formed by uneven skin on the pulp of the human finger at the end of finger, due to the repetition rate of the fingerprint is extremely small, about one in 15 billionth, so fingerprint can be used for recognition. The conventional fingerprint recognition scheme of mobile phone is adding a fingerprint recognition device on the front or back of the mobile phone. The fingerprint recognition can only be performed on the fingerprint recognition device. The fingerprint recognition scheme can only be limited to a limited area of 10 mm² of the fingerprint recognition device, and leads to a poor flexibility, and the additional fingerprint recognition device will increase the cost of the entire apparatus.

### SUMMARY

The technical problem to be solved by the embodiments of the present invention is to provide a mutual capacitance touch display panel with fingerprint recognition and a liquid crystal display apparatus to increase the flexibility of the fingerprinting recognition and reduce costs.

In order to solve the above technical problem, the embodiments of the present invention provide a mutual capacitance touch display panel with fingerprint recognition, including:

A capacitance module, including:

A plurality of first electrodes parallel to each other, and used for fingerprint recognition driving lines;

A plurality of second electrodes parallel to each other, arranged to intersect with the plurality of first electrodes to form a plurality of parasitic capacitances, wherein the second electrodes are used for collection lines for fingerprint recognition;

A first fingerprint recognition chip electrically connected to the first electrodes, respectively, the first fingerprint recognition chip outputting driving signals to the first electrodes in a time division manner;

A second fingerprint recognition chip electrically connected to the second electrodes, respectively, the second fingerprint recognition chip receiving sensing signals of the second electrodes to obtain the parasitic capacitances at intersections of the second electrodes and the first electrodes and obtaining fingerprint data of the user;

A display module, including

A plurality of scan lines parallel to each other;

A plurality of data lines parallel to each other, intersecting disposed with the scan lines, pixel electrodes formed in a region surrounded by the scan lines and the data lines;

A plurality of thin film transistors, a gate of the thin film transistor electrically connected to a corresponding scan line, a source of the thin film transistor electrically connected to a corresponding data line, a drain of the thin film transistor electrically connected to a corresponding pixel electrode;

A gate driver electrically connected to the scan lines respectively; and

A source driver electrically connected to the data lines respectively.

Wherein the mutual capacitance touch display panel is an In-cell mutual capacitance touch display panel.

Wherein the first electrodes are shared with the scan lines of the display module, the second electrodes are shared with the data lines of the display module.

Wherein the first fingerprint recognition chip and the gate driver are located on the same side or different sides of the scan line, the second fingerprint recognition chip and the source driver are located on the same side or different sides of the data line.

Wherein when the first fingerprint recognition chip and the second fingerprint recognition chip are operated, the gate driver and the source driver are not operated, when the gate driver and the source driver are operated, the first fingerprint recognition chip and the second fingerprint recognition chip are not operated.

Wherein when the first fingerprint recognition chip and the second fingerprint recognition chip are operated, a screen of the mutual capacitance touch display panel is turned off.

Wherein a duration of one frame of the mutual capacitive touch display panel includes a display period and a fingerprint recognition period, during the display period, the gate driver and the source driver are operated, during the fingerprint recognition period, the first fingerprint recognition chip and the second fingerprint recognition chip are operated.

Wherein during the fingerprint recognition period, the thin film transistor is in an off state.

Wherein the first fingerprint recognition chip and the second fingerprint recognition chip are respectively fabricated on a flexible circuit board, the flexible circuit boards are press-fitted to an array substrate of the touch display panel; or the first fingerprint recognition chip and the second fingerprint recognition chip are fabricated on the array substrate of the display panel, respectively.

The second embodiment of the present invention provide a mutual capacitance touch display apparatus with fingerprint recognition including the mutual capacitance touch display panel described above.

The implementation of the embodiments of the present invention has the following beneficial effects:

Since the capacitance module includes a plurality of first electrodes parallel to each other and are used for fingerprint recognition driving lines, a plurality of second electrodes parallel to each other and are arranged to intersect with the plurality of first electrodes to form a plurality of parasitic capacitances, the second electrodes are used for collection lines for fingerprint recognition; the first fingerprint recognition chip is electrically connected to the first electrodes, respectively, the first fingerprint recognition chip outputs driving signals to the first electrodes in a time division manner; the second fingerprint recognition chip is electrically connected to the second electrodes, respectively, the second fingerprint recognition chip receives the sensing signals of the second electrodes to obtain the parasitic capacitances at the intersections of the second electrodes and the first electrodes, thereby obtaining the fingerprint data of the user. Therefore, the display area of the display panel can serve as the area for fingerprint recognition, thereby providing greater flexibility. In addition, in the present embodiment, an additional fingerprint recognition device is not to be added, and the cost of the entire apparatus is reduced.

### BRIEF DESCRIPTION OF THE DRAWINGS

Accompanying drawings are for providing further understanding of embodiments of the disclosure. The drawings form a part of the disclosure and are for illustrating the principle of the embodiments of the disclosure along with the literal description. Apparently, the drawings in the description below are merely some embodiments of the disclosure, a person skilled in the art can obtain other drawings according to these drawings without creative efforts. In the figures:

FIG. 1 is a schematic diagram of a mutual capacitance touch display panel according to an embodiment of the present invention.

### DETAILED DESCRIPTION OF PREFERRED EMBODIMENTS

The technical solutions in the embodiments of the present invention will be described clearly and completely hereinafter with reference to the accompanying drawings in the embodiments of the present invention. Apparently, the described embodiments are merely a part but not all embodiments of the present invention. All other embodiments obtained by persons of ordinary skill in the art based on the embodiments of the present invention without creative efforts shall fall within the protection scope of the present invention.

The terms “comprising” and “having,” as well as any variations thereof, appearing in the specification, claims and drawings, are intended to cover the inclusion of non-exclusive. For example, a process, method, system, product, or device that incorporates a series of steps or units is not limited to the steps or units listed but may optionally further include steps or units not listed or may optionally further include other steps or units inherent to these processes, methods, products or devices. In addition, the terms “first”, “second” and “third” are used to distinguish different objects and are not intended to describe a specific order.

An embodiment of the present invention provides a mutual capacitance touch display panel with fingerprint recognition, includes a capacitance module and a display module. The capacitance module recognizes the fingerprint by using the principle of mutual capacitance touch. Specifically, there are differences in capacitances sensed by the convex skin and the concave skin on the finger pulp, by collecting the differences of the capacitance sensed by the finger touching on the mutual capacitance touch display panel, it is possible to restore the appearance of the fingerprint, and further to perform the fingerprint recognition. The display module is used for displaying the image of the display panel.

In the present embodiment, the capacitance module includes a plurality of first electrodes parallel to each other, a plurality of second electrodes parallel to each other, a first fingerprint recognition chip, and a second fingerprint recognition chip.

In the present embodiment, the first electrode extends in a X-axis direction, the first electrodes are disposed in parallel to each other, the number of the first electrodes is N, N is an integer greater than or equal to 2, the N number of first electrodes are uniformly distributed in the display area of the display panel in general, the first electrodes are used for driving lines for the fingerprint recognition, the first electrodes are used for transmitting later-mentioned driving signals.

In the present embodiment, the second electrode extends in a Y-axis direction, the second electrodes are disposed in parallel to each other, the number of the second electrodes is M, the M is an integer greater than or equal to 2, the M number of second electrodes are uniformly distributed in the display area of the display panel in general, each of the first electrodes are intersecting disposed to the second electrodes to form parasitic capacitances at the intersections, so that the number of parasitic capacitances are N*M, the second electrode are used for fingerprint recognition collection lines, and the second electrodes are used for receiving later-mentioned sensing signals.

In the present embodiment, the first fingerprint recognition chip is electrically connected to one end of the first electrodes, respectively, and the first fingerprint recognition chip outputs driving signals to the first electrodes in a time division manner, for example, the first fingerprint recognition chip outputs the driving signal to the first of the first electrode at a first period of time, then, the first fingerprint recognition chip stops outputting the driving signal to the first of the first electrode, then, the first fingerprint recognition chip outputs the driving signal to the second of the first electrode at a second period of time, then, the first fingerprint recognition chip stops outputting the driving signal to the second of the first electrode, . . . , finally, the first fingerprint recognition chip outputs the driving signal to the Nth of the first electrode at a Nth time period of time, then, the first fingerprint recognition chip stops outputting the driving signal to the Nth of the first electrode. In the present embodiment, the driving signal is a sine wave signal, and the first fingerprint recognition chip transmits the driving signals to the first electrodes, the second electrodes intersecting with the first electrode is sensed and generates a sensing signal.

In the present embodiment, the second fingerprint recognition chip is electrically connected to one end of the second electrodes, respectively, and the second fingerprint recognition chip receives the sensing signals from the second electrodes, so that the parasitic capacitances in the intersections of the second electrodes and the first electrodes can be obtained, corresponding to the above embodiments, in the first time period, the second fingerprint recognition chip can obtain data of M number of parasitic capacitances formed at the intersections of the first of the first electrode and the M number of the second electrodes, in the second time period, the second fingerprint recognition chip can obtain data of M number of parasitic capacitances formed at the intersections of the second of the first electrode and the M number of the second electrodes, . . . , and in the Nth time period, the second fingerprint recognition chip can obtain the data of M number of parasitic capacitances formed at the intersections of the Nth of the first electrode and the M number of the second electrodes, therefore to obtain data of N*M number of the parasitic capacitances. Within the N*M parasitic capacitances, in the display panel area where no users finger is placed, the parasitic capacitance in this area is not changed, in the display panel area with the user's finger placed, thereby the parasitic capacitance is reduced due to the presence of the finger, the convex skin and the concave skin on the finger pulp in the end of the finger may have different effects on the parasitic capacitances, thus, the parasitic capacitance corresponding to the convex skin of the finger is different from the parasitic capacitance corresponding to the concave skin of the finger, so that the second fingerprint recognition chip can detect the position of the finger on the display panel, and also detect the fingerprint data of the user's finger.

In the present embodiment, since the capacitance module includes a plurality of first electrodes parallel to each other and used for fingerprint recognition driving lines; the plurality of second electrodes parallel to each other and are arranged to intersect with the plurality of first electrodes to form a plurality of parasitic capacitances, the second electrodes are used for collection lines for fingerprint recognition; the first fingerprint recognition chip is electrically connected to the first electrodes, respectively, the first fingerprint recognition chip outputs driving signals to the first electrodes in a time division manner; the second fingerprint recognition chip is electrically connected to the second electrodes, respectively, the second fingerprint recognition chip receives the sensing signals of the second electrodes to obtain the parasitic capacitances at the intersections of the second electrodes and the first electrodes, thereby obtaining the fingerprint data of the user. Therefore, the display area of the display panel can serve as the area for fingerprint recognition, thereby providing greater flexibility. In addition, in the present embodiment, an additional fingerprint recognition device is not to be added, and the cost of the entire apparatus is reduced. In addition, in the present embodiment, the first electrodes, the second electrodes, the first fingerprint recognition chip and the second fingerprint recognition chip can also be used for detecting the touch position of the finger, so as to be used for achieving the touch detecting, and also be used for fingerprint recognition.

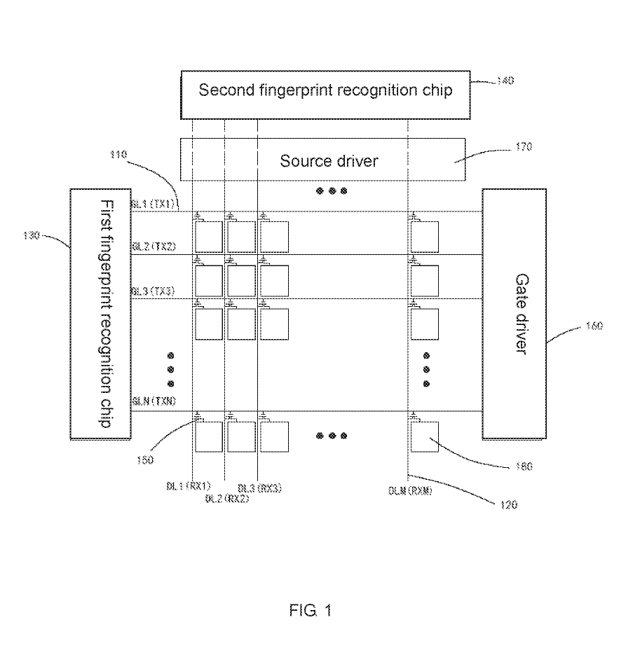

In order to achieve the display function of the display panel, in the present embodiment, the mutual capacitance touch display panel includes the display module (referring to FIG. 1), the display module includes a plurality of scan lines parallel to each other, a plurality of data lines parallel to each other, a plurality of thin film transistors, a gate driver and a source driver.

In the present embodiment, the scan lines extend in the X-axis direction, the data lines extend in the Y-axis direction, the data lines intersect with the scan lines, pixel electrodes are formed in a region surrounded by the intersections of the scan lines and the data lines. A gate of the thin film transistor is electrically connected to a corresponding scan line, a source of the thin film transistor is electrically connected to a corresponding data line, and a drain of the thin film transistor is electrically connected to a corresponding pixel electrode; the gate driver is electrically connected to the scan lines, respectively, the source driver is electrically connected to the data lines, respectively. When the gate driver outputs a high level to one of the scan line, the thin film transistor corresponding to the scan line is turned on, the source driver outputs the data signal to the data line, so that the data signal is transmitted to the corresponding pixel electrode, thereby charging the pixel capacitance. After the pixel capacitor is charged for a certain period of time, the gate driver outputs a low level signal to the scan line, so that the thin film transistor connected to the scan line is turned off, so that the signal on the data line cannot be transmitted to the pixel electrode.

In order to describe the present invention more clearly, an embodiment of the present invention is described below with reference to the accompanying drawings.

Please refer to FIG. 1. In the present embodiment, in order to reduce the cost, and make the display panel thinner, the mutual capacitance touch display panel is an In-cell mutual capacitance touch display panel, of course, in other embodiments of the present invention, the mutual capacitance touch display panel can also be an on-cell mutual capacitance touch display panel. Specifically, in the present embodiment, the first electrodes 110 share the scan lines 110 of the display module, that is, one of the first electrodes 110 and one of the scan lines 110 share one metal line, the second electrode 120 shares the data line 120 of the display module, that is, one of the second electrodes 120 and one of the data lines 120 share one metal line. Here, the number of the first electrodes 110 is the same as the number of the scan lines 110, that is, the first of the first electrode TX1 is shared with the first scan line GL1, the second of the first electrode TX2 is shared with the second scan line GL2, the third of the first electrode TX3 is shared with the third scan line GL3, the Nth of the first electrode TXN is shared with the Nth scan line GLN. The number of the second electrodes 120 is the same as the number of the data lines 120, that is, the first of the second electrode RX1 is shared with the first data line DL1, and the second of the second electrode RX2 is shared with the second data line DL2, the third of the second electrode RX3 is shared with the third data line DL3, . . . , and the Mth second electrode RXM is shared with the Mth data line DLM. Of course, in other embodiments of the present invention, the number of the first electrodes may be less than the number of the scan lines, the number of the second electrodes may be less than the number of the data lines. In this case, the first electrodes are shared with a portion of the scan lines, the second electrodes are shared with a portion of the data lines.

Please continue to refer to FIG. 1, in the present embodiment, the first fingerprint recognition chip 130 and the gate driver 160 are located on different sides of the scan line 110. In the present embodiment, the first fingerprint recognition chip 130 is located on the left side of the scan line 110, the gate driver 160 is located on the right side of the scan line 110, but the present invention is not limited thereto. In other embodiments of the present invention, the first fingerprint recognition chip and the gate driver may also be located on the same side of the scan line, for example, both on the left side or both on the right side. In the present embodiment, the second fingerprint recognition chip 140 and the source driver 170 are located on the same side of the data line 120, here are located on the upper side of the data line 120. However, the present invention is not limited to this, in other embodiments of the present invention, the second fingerprint recognition chip and the source driver may also be located on different sides of the data line. In addition, in the present embodiment, the first fingerprint recognition chip 130 and the gate driver 160 are two separate components, but the present invention is not limited thereto. In other embodiments of the present invention, the first fingerprint recognition chip and the gate driver can also be integrated in one component. Similarly, in the present embodiment, the second fingerprint recognition chip 140 and the source driver 170 are two separate components, but the present invention is not limited thereto. In other embodiments of the present invention, the second fingerprint recognition chip and the source driver can also be integrated in one component.

Since the first electrode 110 is shared with the scan line 110, the second electrode 120 is shared with the data line 120, in order to prevent the gate signal transmitted by the scan line 110 from conflicting with the driving signal transmitted by the scan line 110, the data signal transmitted by the data line 120 conflicting with the sensing signal received by the data line 120. In the present embodiment, when the first fingerprint recognition chip 130 and the second fingerprint recognition chip 140 are operated (the first fingerprint recognition chip is electrically connected to the scan lines and the second fingerprint recognition chip is electrically connected to the data lines), the gate driver 160 and the source driver 170 are not operated, for example, the gate driver 160 and the source driver 170 are electrically disconnected from the scan lines 110 and the data lines 120, respectively through switches, when the gate driver 160 and the source driver 170 are operated (at this time, the gate driver is electrically connected to the scan lines and the source driver is electrically connected to the data lines), the first fingerprint recognition chip 130 and the second fingerprint recognition chip 140 are not operated, for example, the first fingerprint recognition chip 130 and the second fingerprint recognition chip 140 are electrically disconnected from the scan lines 110 and the data lines 120, respectively through switches.

Specifically, in the present embodiment, the first fingerprint recognition chip 130 and the gate driver 160 are operated in the time division manner, the second fingerprint recognition chip 140 and the source driver 170 are operated in the time division manner, the first fingerprint recognition chip 130 and the second fingerprint recognition chip 140 are operated simultaneously, the gate driver 160 and the source driver 170 are operated simultaneously. In the present embodiment, the mutual capacitance touch display panel is driven according to a time period. In the present embodiment, the duration of one period of the mutual capacitance touch display panel is 16.67 ms, that is, the duration of one frame is 16.67 ms, the duration of one frame of the mutual capacitive touch display panel includes a display period and a fingerprint recognition period, during the display period, the gate driver 160 and the source driver 170 are operated, at this period, the first fingerprint recognition chip 130 and the second fingerprint recognition chip 140 are not operated, during the fingerprint recognition period, the first fingerprint recognition chip 130 and the second fingerprint recognition chip 140 are operated, at this period, the gate driver 160 and the source driver 170 are not operated, in the present embodiment, the display period is a charging time of the pixel capacitor, the fingerprint recognition period is a blanking time, of course, in other embodiments of the present invention, the fingerprint recognition period can also be included in the blanking time,

In the present embodiment, during the fingerprint recognition period, the display panel is turned on, and an image is displayed at this time. In order to prevent the variation of the image of the display panel and prevent the discharge of the liquid crystal capacitor from affecting the detection of the parasitic capacitance, in the present embodiment, during the fingerprint recognition period, the thin film transistor 150 is turned off, that is, the data line 120 is disconnected from the pixel electrode 180 at this time, the pixel capacitor cannot discharge outward. In the present embodiment, in order to achieve the off state of the thin film transistor 150 during the fingerprint recognition period, the high level of the driving signal is, for example, a negative voltage, for example, −7V, −7.5V, −8V and other voltages, the low level of the driving signal is, for example, −9V, −9.5V, −10V and other voltages. Of course, in other embodiments of the present invention, when the first fingerprint recognition chip and the second fingerprint recognition chip are operated, the screen of the mutual capacitance touch display panel is turned off, at this time, the screen can be unlocked by the capacitance module for recognizing the fingerprint.

In the present embodiment, the display panel includes an array substrate, a color filter substrate opposite to the array substrate, and a liquid crystal layer disposed between the array substrate and the color filter substrate. In the present embodiment, the first fingerprint recognition chip 130 and the second fingerprint recognition chip 140 are respectively fabricated on a flexible circuit board, FPC, that is the flexible circuit boards are press-fitted to the array substrate of the touch display panel, so that the first fingerprint recognition chip 130 is electrically connected to the scan lines 110, the second fingerprint recognition chip 140 is electrically connected to the data line 120. However, the present invention is not limited thereto. In other embodiments of the present invention, the first fingerprint recognition chip and the second fingerprint recognition chip may be formed on the array substrate of the display panel, respectively. In the present embodiment, the gate driver 160 and the source driver 170 are directly formed on the array substrate. However, the present invention is not limited thereto. In other embodiments of the present invention, the gate driver and the source driver may also be fabricated on the flexible circuit board.

In addition, an embodiment of the present invention further provides a mutual capacitance touch display apparatus includes the above-mentioned mutual capacitance touch display panel with fingerprint recognition and a backlight module, the backlight module is located below the mutual capacitance touch display panel, and is for providing light source to the mutual capacitance touch display panel.

It should be noted that, each embodiment in this specification is described in a progressive manner, and each embodiment focuses on differences from other embodiments. The same and similar parts among the embodiments can be referred to each other. For the apparatus embodiment, since the method is basically similar to the method embodiment, the description is relatively simple. For the relevant part, reference may be made to part of the method embodiment.

Through the description of the above embodiments, the present invention has the following advantages:

Since the capacitance module includes a plurality of first electrodes parallel to each other and are used for fingerprint recognition driving lines, a plurality of second electrodes parallel to each other and are arranged to intersect with the plurality of first electrodes to form a plurality of parasitic capacitances, the second electrodes are used for collection lines for fingerprint recognition; the first fingerprint recognition chip is electrically connected to the first electrodes, respectively, the first fingerprint recognition chip outputs driving signals to the first electrodes in a time division manner; the second fingerprint recognition chip is electrically connected to the second electrodes, respectively, the second fingerprint recognition chip receives the sensing signals of the second electrodes to obtain the parasitic capacitances at the intersections of the second electrodes and the first electrodes, thereby obtaining the fingerprint data of the user. Therefore, the display area of the display panel can serve as the area for fingerprint recognition, thereby providing greater flexibility. In addition, in the present embodiment, an additional fingerprint recognition device is not to be added, and the cost of the entire apparatus is reduced.

The foregoing contents are detailed description of the disclosure in conjunction with specific preferred embodiments and concrete embodiments of the disclosure are not limited to these descriptions. For the person skilled in the art of the disclosure, without departing from the concept of the disclosure, simple deductions or substitutions can be made and should be included in the protection scope of the application.

What is claimed is:

1. A mutual capacitance touch display panel with fingerprint recognition, comprising:
a capacitance module, comprising:
a plurality of first electrodes parallel to each other, and used for fingerprint recognition driving lines;
a plurality of second electrodes parallel to each other, arranged to intersect with the plurality of first electrodes to form a plurality of parasitic capacitances, wherein the second electrodes are used for collection lines for fingerprint recognition;
a first fingerprint recognition chip electrically connected to the first electrodes, respectively, the first fingerprint recognition chip outputting driving signals to the first electrodes in a time division manner;
a second fingerprint recognition chip electrically connected to the second electrodes, respectively, the second fingerprint recognition chip receiving sensing signals of the second electrodes to obtain the parasitic capacitances at intersections of the second electrodes and the first electrodes and obtaining fingerprint data of the user;
a display module, comprising
a plurality of scan lines parallel to each other;
a plurality of data lines parallel to each other, intersecting disposed with the scan lines, pixel electrodes formed in a region surrounded by the scan lines and the data lines;
a plurality of thin film transistors, a gate of the thin film transistor electrically connected to a corresponding scan line, a source of the thin film transistor electrically connected to a corresponding data line, a drain of the thin film transistor electrically connected to a corresponding pixel electrode;
a gate driver electrically connected to the scan lines respectively; and
a source driver electrically connected to the data lines respectively.

2. The mutual capacitance touch display panel with fingerprint recognition according to claim 1, wherein the mutual capacitance touch display panel is an In-cell mutual capacitance touch display panel.

3. The mutual capacitance touch display panel with fingerprint recognition according to claim 2, wherein the first electrodes are shared with the scan lines of the display module, the second electrodes are shared with the data lines of the display module.

4. The mutual capacitance touch display panel with fingerprint recognition according to claim 3, wherein the first fingerprint recognition chip and the gate driver are located on the same side or different sides of the scan line, the second fingerprint recognition chip and the source driver are located on the same side or different sides of the data line.

5. The mutual capacitance touch display panel with fingerprint recognition according to claim 3, wherein when the first fingerprint recognition chip and the second fingerprint recognition chip are operated, the gate driver and the source driver are not operated, when the gate driver and the source driver are operated, the first fingerprint recognition chip and the second fingerprint recognition chip are not operated.

6. The mutual capacitance touch display panel with fingerprint recognition according to claim 5, wherein when the first fingerprint recognition chip and the second fingerprint recognition chip are operated, a screen of the mutual capacitance touch display panel is turned off.

7. The mutual capacitance touch display panel with fingerprint recognition according to claim 5, wherein a duration of one frame of the mutual capacitive touch display panel comprises a display period and a fingerprint recognition period, during the display period, the gate driver and the source driver are operated, during the fingerprint recognition period, the first fingerprint recognition chip and the second fingerprint recognition chip are operated.

8. The mutual capacitance touch display panel with fingerprint recognition according to claim 7, wherein during the fingerprint recognition period, the thin film transistor is in an off state,

9. The mutual capacitance touch display panel with fingerprint recognition according to claim 3, wherein the first fingerprint recognition chip and the second fingerprint recognition chip are respectively fabricated on a flexible circuit board, the flexible circuit boards are press-fitted to an array substrate of the touch display panel; or the first fingerprint recognition chip and the second fingerprint recognition chip are fabricated on the array substrate of the display panel, respectively.

10. A mutual capacitance touch display apparatus with fingerprint recognition, comprising a mutual capacitance touch display panel, wherein the mutual capacitance touch display panel comprises:
a capacitance module, comprising:
a plurality of first electrodes parallel to each other, and used for fingerprint recognition driving lines;
a plurality of second electrodes parallel to each other, arranged to intersect with the plurality of first electrodes to form a plurality of parasitic capacitances, wherein the second electrodes are used for collection lines for fingerprint recognition;
a first fingerprint recognition chip electrically connected to the first electrodes, respectively, the first fingerprint recognition chip outputting driving signals to the first electrodes in a time division manner;
a second fingerprint recognition chip electrically connected to the second electrodes, respectively, the second fingerprint recognition chip receiving sensing signals of the second electrodes to obtain the parasitic capacitances at intersections of the second electrodes and the first electrodes and obtaining fingerprint data of the user;
a display module, comprising
a plurality of scan lines parallel to each other;
a plurality of data lines parallel to each other, intersecting disposed with the scan lines, pixel electrodes formed in a region surrounded by the scan lines and the data lines;
a plurality of thin film transistors, a gate of the thin film transistor electrically connected to a corresponding scan line, a source of the thin film transistor electrically connected to a corresponding data line, a drain of the thin film transistor electrically connected to a corresponding pixel electrode;
a gate driver electrically connected to the scan lines respectively; and
a source driver electrically connected to the data lines respectively.

11. The mutual capacitance touch display apparatus with fingerprint recognition according to claim 10, wherein the mutual capacitance touch display panel is an In-cell mutual capacitance touch display panel.

12. The mutual capacitance touch display apparatus with fingerprint recognition according to claim 11, wherein the first electrodes are shared with the scan lines of the display module, the second electrodes are shared with the data lines of the display module.

13. The mutual capacitance touch display apparatus with fingerprint recognition according to claim 12, wherein the first fingerprint recognition chip and the gate driver are located on the same side or different sides of the scan line, the second fingerprint recognition chip and the source driver are located on the same side or different sides of the data line.

14. The mutual capacitance touch display apparatus with fingerprint recognition according to claim 12, wherein when the first fingerprint recognition chip and the second fingerprint recognition chip are operated, the gate driver and the source driver are not operated, when the gate driver and the source driver are operated, the first fingerprint recognition chip and the second fingerprint recognition chip are not operated.

15. The mutual capacitance touch display apparatus with fingerprint recognition according to claim 14, wherein when the first fingerprint recognition chip and the second fingerprint recognition chip are operated, a screen of the mutual capacitance touch display panel is turned off.

16. The mutual capacitance touch display apparatus with fingerprint recognition according to claim 14, wherein a duration of one frame of the mutual capacitive touch display panel comprises a display period and a fingerprint recognition period, during the display period, the gate driver and the source driver are operated, during the fingerprint recognition period, the first fingerprint recognition chip and the second fingerprint recognition chip are operated.

17. The mutual capacitance touch display apparatus with fingerprint recognition according to claim 16, wherein during the fingerprint recognition period, the thin film transistor is in an off state.

18. The mutual capacitance touch display apparatus with fingerprint recognition according to claim 12, wherein the first fingerprint recognition chip and the second fingerprint recognition chip are respectively fabricated on a flexible circuit board, the flexible circuit boards are press-fitted to an array substrate of the touch display panel; or the first fingerprint recognition chip and the second fingerprint recognition chip are fabricated on the array substrate of the display panel, respectively.
